(19) United States
(12) Patent Application Publication
(10) Pub. No.: US 2020/0091765 A1
(43) Pub. Date: Mar. 19, 2020

(54) METHODS AND SYSTEMS FOR ASSESSING HOSTING CAPACITY IN A DISTRIBUTION SYSTEM

(71) Applicant: Commonwealth Edison Company, Chicago, IL (US)

(72) Inventors: SHAY BAHRAMIRAD, Oakbrook Terrace, IL (US); Peter Tyschenko, Oakbrook Terrace, IL (US); Aleksi Passo, Oakbrook Terrace, IL (US); Kazi Moyeen-ul Huq, Raleigh, NC (US); Gerardo Sanchez-Ayala, Raleigh, NC (US); Vahraz Zamani, Raleigh, NC (US)

(21) Appl. No.: 16/569,327

(22) Filed: Sep. 12, 2019

Related U.S. Application Data
(60) Provisional application No. 62/731,530, filed on Sep. 14, 2018.

(51) Int. Cl. H02J 13/00; G01R 21/133; H02J 3/00

(52) U.S. Cl. CPC H02J 13/0006; H02J 3/00; G01R 21/133

(57) ABSTRACT

Methods and systems are described for determining a distribution system's hosting capacity for distributed power generation. Hosting capacity may be assessed on a feeder-by-feeder basis. Performing a hosting capacity assessment may include randomly selecting spot load points in a feeder as candidates for installation of distributed power generation sources. The hosting capacity assessment may be repeated a number of times to ensure optimal results and to correct for any violations of system performance parameters caused by an addition of distributed power generation at a given spot load point.

### CROSS REFERENCE TO RELATED PATENT APPLICATION

This application claims priority to U.S. Provisional Application No. 62/731,530, filed on Sep. 14, 2018, which is herein incorporated by reference in its entirety.

### BACKGROUND

A hosting capacity analysis of a distribution system seeks to determine an amount of electrical power that can be generated at one or more points in the distribution system, such as at locations coupled to distribution system feeders. Hosting capacity analyses are therefore concerned with electrical power that is produced within a distribution system itself, rather than at an electrical power plant. Sources of such internal power generation include distributed generators, which are small units of power generation that are directly connected to a distribution system and are in close proximity to the system's customers. In recent years the use of distributed generators has grown significantly, due to the falling cost of associated technology as well as promising benefits for end-use customers, such as payment reduction and potential improvement to system reliability. Customers who use distributed generators, unlike most power utility customers, have the ability to produce electricity and, in some circumstances, sell surplus energy back to the utility company. Among available distributed generator technologies, solar photovoltaic (“PV”) and small-scale wind turbines are projected to be the most widely adopted platforms.

The information provided by a hosting capacity analysis is significant and allows for improved planning, maintenance, operation, and control of distribution systems and associated power grids. Further, given the complexity of distribution systems, approaches to assessing hosting capacity must consider an array of factors. Some existing methods and systems focus on certain factors to the detriment of considering more important factors. Moreover, existing methods and systems are unable to perform a hosting capacity assessment when imperfect or missing information related to the distribution system being analyzed is present in input data. These and other shortcomings are addressed by the methods and systems described herein.

### SUMMARY

It is to be understood that both the following general description and the following detailed description are exemplary and explanatory only and are not restrictive. Methods and systems are described herein for assessing a hosting capacity for one or more points in a power distribution system. The methods and systems can be configured to receive feeder data associated with a plurality of distribution system feeders. Such feeder data may represent electrical loads, node types, and other aspects of the plurality of feeders in the distribution system. Determining a given feeder's hosting capacity may include several steps. A subset of spot loads from among a plurality of spot loads may first be generated by the methods and systems, and each spot load in the subset may have one or more associated characteristics, such as customer type and a number of kilowatts.

Further, one or more spot loads in the subset may be associated with an amount of distributed power generation to be added to a specific spot load point of a plurality of spot load points coupled to the feeder being analyzed. At random, spot load points may be selected as a candidate for installation of a distributed power generation source. A value of kilowatts corresponding to each randomly selected spot load point may be increased by an amount equal to one of the generated spot loads, and a power flow may then be generated for the given spot load point using the increased value of kilowatts. If any performance parameters associated with the feeder or distribution system overall are violated when a candidate spot load point is assessed with an increased kilowatt value, then the methods and systems may employ troubleshooting measures such that the particular spot load point causing the violation has its corresponding kilowatt value reduced by an amount equal to the previously increased amount.

The methods and systems may then determine an overall hosting capacity contribution of each feeder in the distribution system, which may be based on a selection among a determined first or a second hosting capacity contribution. The first hosting capacity contribution may be associated with a peak or maximum load for the given feeder. Conversely, the second hosting capacity contribution may be associated with a minimum load for the given feeder. The overall hosting capacity contribution for a given feeder may then be based on the first hosting capacity contribution of the given feeder when the second hosting capacity contribution of the given feeder is greater than the first hosting capacity contribution. Alternatively, the overall hosting capacity contribution for the given feeder may be based on the second hosting capacity contribution of the given feeder when the first hosting capacity contribution of the given feeder is greater than the second hosting capacity contribution. Additional advantages will be set forth in part in the description which follows or may be learned by practice. The advantages will be realized and attained by means of the elements and combinations particularly pointed out in the appended claims.

### BRIEF DESCRIPTION OF THE DRAWINGS

The accompanying drawings, which are incorporated in and constitute a part of this specification, illustrate embodiments and together with the description, serve to explain the principles of the methods and systems:

FIG. 1 is a block diagram of an exemplary computing device;

FIG. 2 depicts a schematic diagram of a distribution system;

FIG. 3 depicts an exemplary process flow;

FIG. 4 depicts an exemplary spreadsheet of hosting capacity results;

FIG. 5 is a screenshot of exemplary hosting capacity assessment options;

FIG. 6A depicts an exemplary graphical user interface;

FIG. 6B depicts an exemplary graphical user interface;

FIG. 7A is a flowchart of an exemplary method; and

FIG. 7B is a flowchart of an exemplary method.

### DETAILED DESCRIPTION

Before the present methods and systems are disclosed and described, it is to be understood that the methods and systems are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Disclosed are components that can be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all aspects of this application including, but not limited to, steps in disclosed methods. Thus, if there are a variety of additional steps that can be performed it is understood that each of these additional steps can be performed with any specific embodiment or combination of embodiments of the disclosed methods. The present methods and systems may be understood more readily by reference to the following detailed description of preferred embodiments and the examples included therein and to the Figures and their previous and following description.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described below with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, can be implemented by computer program instructions. These computer program instructions may be loaded onto a general purpose computer, special purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

Accordingly, blocks of the block diagrams and flowchart illustrations support combinations of means for performing the specified functions, combinations of steps for performing the specified functions and program instruction means for performing the specified functions. It will also be understood that each block of the block diagrams and flowchart illustrations, and combinations of blocks in the block diagrams and flowchart illustrations, can be implemented by special purpose hardware-based computer systems that perform the specified functions or steps, or combinations of special purpose hardware and computer instructions. The present methods and systems can be used for, among other things, determining a hosting capacity for a given feeder in a distribution network. As will be discussed in further detail below, the present methods and systems improve upon existing methods and systems in terms of required data input, ability to account for imperfect input data, computational efficiency, and accuracy.

The present methods and systems may be more operationally efficient or accurate than existing hosting capacity assessment tools. The present methods and systems thus gain the capability of assessing hosting capacity of a large number of distribution network feeders in a manageable time frame (e.g., greater computational efficiency than existing assessment tools). Further, the present methods and systems improve existing assessment tools by offering additional user options, increased functionality, an improved graphical user interface, and a higher level of robustness in terms of accounting for imperfect source data related to one or more of the feeders being assessed. The present methods and systems are compatible with several commercially available assessment tool formats, such as the CYMDIST self-contained format. Additionally, the present methods and systems may determine an amount of distributed power generation that a given feeder can tolerate without violating performance indicators associated with the feeder, such as voltage level, loading percentage, reverse power flow, etc. When assessing a given feeder to determine its hosting capacity, the present methods and systems may randomly assign spot loads (e.g., an amount of power provided by a source of distributed power generation) in such a way as to emulate the natural growth of distributed generation (e.g., an approach that is stochastic in nature). As such, the present methods and systems may only consider nodes (e.g., spot load points) of a given feeder that service customers where distributed power generation is feasible (e.g., rooftop locations for PV generation; nearby open spaces for small or large-scale wind turbine installation, etc.).

As previously mentioned, the present methods and systems represent an improvement to existing technological approaches for assessing hosting capacity. One such existing assessment tool was built using Microsoft's® Visual Basic code, and it interacts with CYMDIST software using a CYME COM module. This existing assessment tool allows the implementation of the basic architecture and philosophy of a hosting capacity assessment, but it is not effective when considering a large number of feeders due to time constraints (e.g., computational inefficiency inherent in the implementation). With this existing tool, hosting capacity is determined by gradually increasing distributed power generation at each node of a feeder, one by one. At every new generation step, the feeder is checked against a set of pre-defined selectable performance criteria (e.g., nodal voltage variations and absolute nodal voltage, element loading level, reverse power flow, protection, etc.). Further, this existing approach only considers a limited number of performance parameters (e.g., feeder over-voltage) when determining a hosting capacity, and it requires near perfect input data (e.g., no load values or customer data information is missing from the input data). Moreover, this existing approach performs iterative power flow simulations to model an impact of distributed power generation at each node (e.g., a node-by-node analysis approach rather than a feeder-by-feeder approach).

Another existing assessment tool uses a three-step approach when assessing a feeder's hosting capacity. The first step includes gradually increasing distributed power generation at every individual node of a feeder. It should be noted that with this existing approach the assessment must be stopped when an exception is found. At the second step, distributed power generation is added randomly and gradually to specified feeder nodes, and the assessment tool can assign different growth profiles for commercial and for residential customer nodes. At the third step, a maximum amount of distributed power generation is determined for each section of the feeder while considering load and generation profiles on a 24-hour period. This approach however requires a user to manually designate the specific nodes to consider, and it does not incorporate existing distributed power generation in the analysis. This existing approach also does not lock regulation equipment during the assessment. By allowing regulation equipment to operate during an assessment, the determined hosting capacity may be overestimated in some cases.

A third existing assessment tool utilizes a set of algorithms to estimate hosting capacity at each feeder after performing an initial baseline power flow and short circuit simulation to determine a starting point. This existing approach may offer some reduction in computing time, while the iterative method discussed above provides a higher degree of accuracy. However, similar to other existing assessment tools, this approach requires perfect input data for each feeder.

The present method and systems seek to ameliorate the defects of existing assessment tools. Compatibility with the CYMDIST self-contained format is preserved while also allowing hosting capacity to be determined on a feeder-by-feeder basis rather than a node-by-node basis. The present methods and systems may therefore (i) improve the time it takes to assess each feeder, (ii) incorporate additional constraint verifications, (iii) consider peak and light load scenarios, and (iv) account for missing or imperfect input data. Any combination of constraints may be selected and evaluated when assessing a hosting capacity of a given feeder. These constraints may be overvoltage, under-voltage, reverse power flow, thermal overloading, and the like. In order to account for imperfect or missing input data, the present methods and systems may analyze input data to determine whether any spot load data (e.g., characteristics associated with a particular location in a feeder) is missing customer information (e.g., type of customer, such as residential or commercial or industrial) or missing load data (e.g., a number of kilowatt). Any missing customer information may be determined based on corresponding kilowatts values. Similarly, missing load data may be determined using a corresponding customer type. If both customer data and load data are missing for a given spot load, then it may be excluded from the analysis.

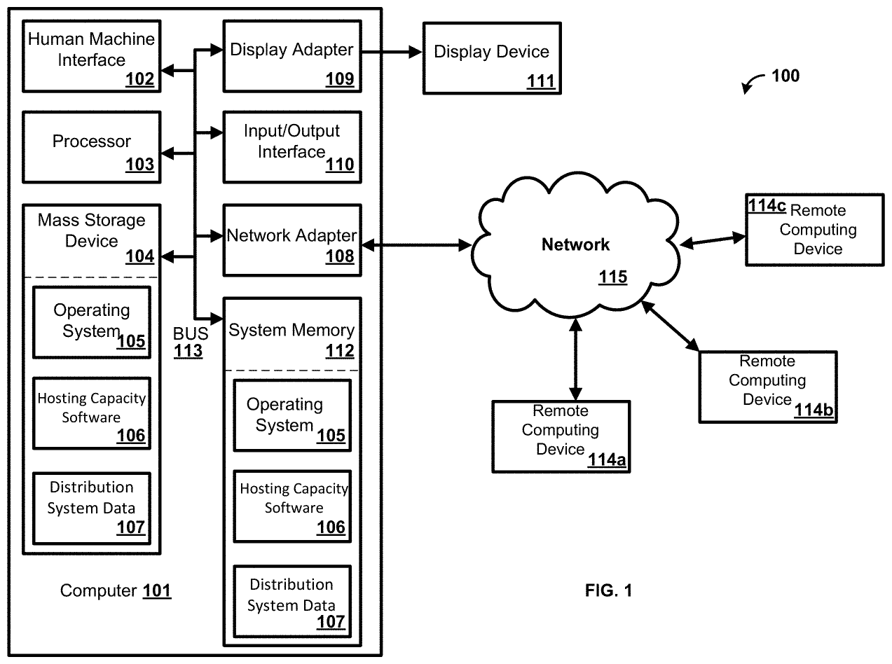

Turning now to the several figures, FIG. 1 depicts a computer 101 with which the present methods and systems may be implemented. Similarly, the present methods and systems may utilize two or more computers 101 to perform one or more functions in one or more locations. FIG. 1 is a block diagram illustrating an exemplary operating environment for performing the disclosed methods. This exemplary operating environment is only an example of an operating environment and is not intended to suggest any limitation as to the scope of use or functionality of operating environment architecture. Neither should the operating environment be interpreted as having any dependency or requirement relating to any one or combination of components illustrated in the exemplary operating environment.

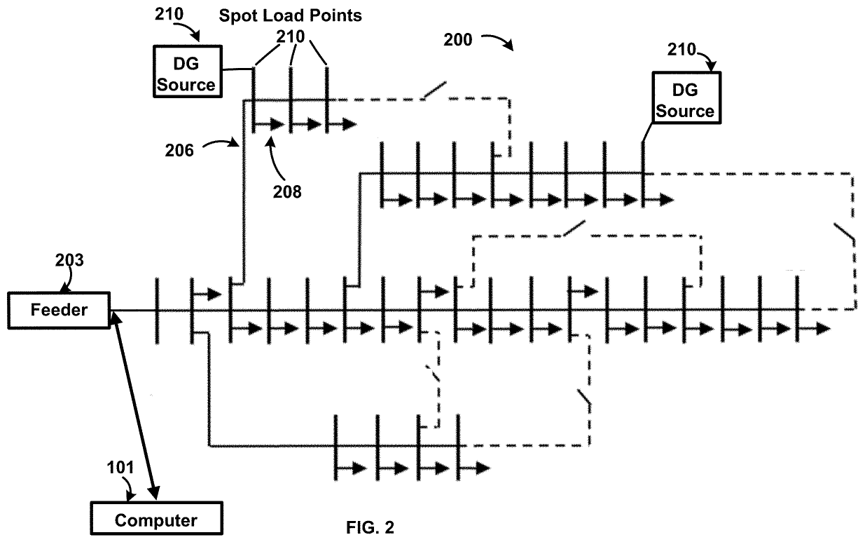

The methods and systems described herein (e.g., method 700) may be implemented on a computer 101 connected to a power distribution system (e.g., distribution system 200 shown in FIG. 2). Computer 101 can be operational with numerous general purpose or special purpose computing system environments or configurations. Examples of well-known computing systems, environments, and/or configurations that can be suitable for use with computer 101 can be, but are not limited to, personal computers, server computers, laptop devices, and/or multiprocessor systems. Additional examples are network PCs, minicomputers, mainframe computers, distributed computing environments that comprise any of the above systems or devices, and the like.

Computer 101 can use software components when implementing the present methods and systems. Further, the present methods and systems can be described in the general context of computer-executable instructions, such as program modules, being executed by one or more computers or other devices. Generally, program modules comprise computer code, routines, programs, objects, components, data structures, etc., that perform particular tasks or implement particular abstract data types. The methods and systems can also be practiced in distributed computing environments where tasks are performed by remote processing devices that are linked through a communications network. In a distributed computing environment, program modules can be located in both local and remote computer storage media including memory storage devices.

The components of the computer 101 can include, but are not limited to, one or more processors 103, a system memory 112, and a bus 113 that couples various system components including the one or more processors 103 to the system memory 112. The system can utilize parallel computing. The bus 113 represents one or more of several possible types of bus structures, including a memory bus or memory controller, a peripheral bus, an accelerated graphics port, or local bus using any of a variety of bus architectures. By way of example, such architectures can comprise an Industry Standard Architecture (ISA) bus, a Micro Channel Architecture (MCA) bus, an Enhanced ISA (EISA) bus, a Video Electronics Standards Association (VESA) local bus, an Accelerated Graphics Port (AGP) bus, and a Peripheral Component Interconnects (PCI), a PCI-Express bus, a Personal Computer Memory Card Industry Association (PCMCIA), Universal Serial Distribution bus (USB) and the like. The bus 113, and all buses specified in this description, can also be implemented over a wired or wireless network connection and each of the subsystems, including the one or more processors 103, a mass storage device 104, an operating system 105, hosting capacity software 106, distribution network data 107, a network adapter 108, the system memory 112, an Input/Output Interface 110, a display adapter 109, a display device 111, and a human machine interface 102, can be contained within one or more remote computing devices 114a,b,c at physically separate locations, connected through buses 112 of this form, in effect implementing a fully distributed system.

The computer 101 typically has a variety of computer readable media. Exemplary readable media can be any available media that is accessible by the computer 101 and comprises, for example and not meant to be limiting, both volatile and non-volatile media, removable and non-removable media. The system memory 112 comprises computer readable media in the form of volatile memory, such as random access memory (RAM), and/or non-volatile memory, such as read only memory (ROM). The system memory 112 typically contains data such as the distribution network data 107 and/or program modules such as the operating system 105 and the hosting capacity software 106 that are immediately accessible to and/or are presently operated on by the one or more processors 103.

In another aspect, the computer 101 can also comprise other removable/non-removable, volatile/non-volatile computer storage media. By way of example, FIG. 1 illustrates the mass storage device 104 which can provide non-volatile storage of computer code, computer readable instructions, data structures, program modules, and other data for the computer 101. For example and not meant to be limiting, the mass storage device 104 can be a hard disk, a removable magnetic disk, a removable optical disk, magnetic cassettes or other magnetic storage devices, flash memory cards, CD-ROM, digital versatile disks (DVD) or other optical storage, random access memories (RAM), read only memories (ROM), electrically erasable programmable read-only memory (EEPROM), and the like.

Optionally, any number of program modules can be stored on the mass storage device 104, including by way of example, the operating system 105 and the hosting capacity software 106. Each of the operating system 105 and the hosting capacity software 106 (or some combination thereof) can comprise elements of the programming and the hosting capacity software 106. The distribution network data 107 can also be stored on the mass storage device 104. The distribution network data 107 can be stored in any of one or more databases known in the art. Examples of such databases comprise, DB2®, Microsoft® Access, Microsoft® SQL Server, Oracle®, mySQL, PostgreSQL, and the like. The databases can be centralized or distributed across multiple systems.

In another aspect, the user can enter commands and information into the computer 101 via an input device (not shown). Examples of such input devices comprise, but are not limited to, a keyboard, pointing device (e.g., a “mouse”), a microphone, a joystick, a scanner, tactile input devices such as gloves, and other body coverings, and the like These and other input devices can be connected to the one or more processors 103 via the human machine interface 102 that is coupled to the bus 113, but can be connected by other interface and distribution bus structures, such as a parallel port, game port, an IEEE 1394 Port (also known as a Firewire port), a serial port, or a universal serial bus (USB).

In yet another aspect, the display device 111 can also be connected to the bus 113 via an interface, such as the display adapter 109. It is contemplated that the computer 101 can have more than one display adapter 109 and the computer 101 can have more than one display device 111. For example, a display device can be a monitor, an LCD (Liquid Crystal Display), or a projector. In addition to the display device 111, other output peripheral devices can comprise components such as speakers (not shown) and a printer (not shown) which can be connected to the computer 101 via the Input/Output Interface 110. Any step and/or result of the present methods (e.g., method 200 and/or method 700) can be output in any form to an output device. Such output can be any form of visual representation, including, but not limited to, textual, graphical, animation, audio, tactile, and the like. The display 111 and computer 101 can be part of one device, or separate devices.

The computer 101 can operate in a networked environment using logical connections to one or more remote computing devices 114a,b,c. By way of example, a remote computing device can be a personal computer, portable computer, a server, a router, a network computer, a peer device or other common network node, and so on. Logical connections between the computer 101 and a remote computing device 114a,b,c can be made via a network 115, such as a local area network (LAN) and/or a general wide area network (WAN). Such network connections can be through the network adapter 108. The network adapter 108 can be implemented in both wired and wireless environments.

For purposes of illustration, application programs and other executable program components such as the operating system 105 are illustrated herein as discrete blocks, although it is recognized that such programs and components reside at various times in different storage components of the computing device 101, and are executed by the one or more processors 103 of the computer. An implementation of the hosting capacity software 106 can be stored on or transmitted across some form of computer readable media. Any of the disclosed methods can be performed by computer readable instructions embodied on computer readable media. Computer readable media can be any available media that can be accessed by a computer. By way of example and not meant to be limiting, computer readable media can comprise “computer storage media” and “communications media.”

The computing device 101, executing the hosting capacity software 106, can be configured to receive feeder data (e.g., distribution network data 107 retrieved from the system memory 112, mass storage device 104, or network 115) representing electrical loads, node types, and other aspects of a plurality of feeders in a distribution system, including a group of performance parameters (e.g., overvoltage, under-voltage, reverse power flow, thermal overloading, etc.). Using the processor 103 and the feeder data, the hosting capacity software 106 can determine a hosting capacity for the distribution system, which can then be stored in system memory 112 or mass storage device 104, or, optionally, to network 115. Determining the hosting capacity can include several steps. First, the hosting capacity software 106 can generate a subset of spot loads from among a plurality of spot loads, each spot load having one or more characteristics (e.g., anomalous characteristics, non-anomalous characteristics, etc.) relating to the spot load (e.g., customer type, a number of kilowatts, etc.). A spot load may be associated with an amount of distributed power “DG” generation (e.g., from photovoltaic “PV” generation; wind mill generation; etc.).

In generating the subset of spot loads, the hosting capacity software 106 can determine whether each characteristic associated with each of the plurality of spot loads is anomalous or non-anomalous (e.g., expected vs. not expected; compatible with the hosting capacity software 106 vs. not compatible; etc.). The hosting capacity software 106 may modify a state of at least one anomalous characteristic such that the modified state is indicative of the characteristic being non-anomalous. Such a modification may include the hosting capacity software 106 determining a customer type (e.g., residential, commercial, industrial, mixed-use, etc.) associated with a value of a first characteristic of a given spot load (e.g., a number of kilowatts). After determining the customer type, the hosting capacity software 106 may then modify a state of the first characteristic of the given spot load determined to be anomalous (e.g., having a number of kilowatts indicative of zero). The modification may be based on the customer type (e.g., a residential customer may be associated with a lesser number of kilowatts than a commercial or industrial customer). Next, the hosting capacity software 106 may then generate the subset of spot loads, which may include one or more of the plurality of spot loads. Further all spot loads in the subset may only have characteristics that are non-anomalous (e.g., no kilowatt values indicative of zero; no customer types with a null/empty value).

After the hosting capacity software 106 generates the subset of spot loads, it may then determine a hosting capacity contribution of each of the plurality of distribution system feeders. Each hosting capacity contribution may be based on the subset of spot loads and the plurality of performance parameters (e.g., an aggregate of each spot load of the subset). Further, determining each hosting capacity contribution may include a series of steps (a)-(g). At step (a), the hosting capacity software 106 may randomly select a spot load from among the subset of spot loads. Next, at step (b), the hosting capacity software 106 may adjust a number of kilowatts associated with a characteristic (e.g., kilowatts of PV or DG power generation at the particular spot load) of the randomly selected spot load by a specified amount (e.g., an amount indicative of a peak load; an amount indicative of a minimum load; etc.). The hosting capacity software 106 may then, at step (c), generate a load flow for the feeder (e.g., a representation of electrical flow in the feeder) based on the adjusted number of kilowatts (e.g., the load flow may change depending on the adjusted amount).

Next, at step (d), the hosting capacity software 106 may determine whether any of the plurality of performance parameters is violated (e.g., load overflow; greater PV or DG generation than permitted). Determining whether any of the plurality of performance parameters is violated may be based on the load flow for the feeder (e.g., the load flow determined a step (c)). At step (e) the hosting capacity software 106 may, after determining that the plurality of performance parameters are not violated, repeat steps (a)-(d) for each spot load of the subset of spot loads (e.g., repeating the steps for every spot load in the subset). At step (f), the hosting capacity software 106 may, after determining that at least one of the plurality of performance parameters is violated, decrease the number of kilowatts associated with the characteristic of the previously selected spot load by the adjusted amount(e.g., eliminate the kilowatts of additional PV or DG power generation at the particular spot load). Finally, at step (g), the hosting capacity software 106 may then determine a first hosting capacity contribution for the given feeder based on the generated load flows for the feeder. Optionally, the hosting capacity software 106 may repeat steps (a)-(g) for each feeder such that the adjusted amount is indicative of a minimum load for the given feeder (e.g., resulting in a second hosting capacity contribution for each feeder).

An overall hosting capacity contribution for a given feeder may be based on the first hosting capacity contribution of the given feeder when the second hosting capacity contribution of the given feeder is greater than the first hosting capacity contribution. Alternatively, the overall hosting capacity contribution for the given feeder may be based on the second hosting capacity contribution of the given feeder when the first hosting capacity contribution of the given feeder is greater than the second hosting capacity contribution. Further, using the processor 103 and the hosting capacity software 106, all determined values and data discussed above can be stored in the system memory 112, mass storage device 104, and/or to network 115.

The methods and systems implemented on the computer 101 may employ Artificial Intelligence techniques such as machine learning and iterative learning. Examples of such techniques include, but are not limited to, expert systems, case based reasoning, Bayesian networks, behavior based AI, neural networks, fuzzy systems, evolutionary computation (e.g. genetic algorithms), swarm intelligence (e.g. ant algorithms), and hybrid intelligent systems (e.g. Expert inference rules generated through a neural network or production rules from statistical learning).

Turning now to FIG. 2, an example distribution system 200 on which the methods and systems described herein may be employed is depicted. The distribution system 200 may be arranged in a tree-type configuration with a feeder 203 coupled to one or more distribution lines 206 connected to one more one spot load points 210, each of which having a given electrical load 208. The one or more distribution lines 206 may be connected to any number of the one or more spot load points 210 using a variety of suitable configurations known in the art. The one or more spot load points 210 may have a range of designs, including, for example, being housed within switchgear, panel boards, and/or busway enclosures—all of which being capable of withstanding a variety of electrical loads 208. The one or more spot load points 210 may be connected to high voltage equipment at electrical switchyards, low voltage equipment in battery banks, residential transformers, or the like. The distribution system 200 may also comprise one or more distributed power generation sources 210, each of which being situated at a given spot load point 210 and being capable of providing electrical power through distribution lines 206. The one or more distributed power generation sources 210 may be one or more solar photovoltaic (“PV”) panels, one or more wind turbines, or the like, located at commercial locations and/or residential locations. Further, the computer 101 may be in communication with the feeder 203 via wired or wireless means. It is to be understood that the distribution system layout described herein (e.g., distribution system 200) is for illustrative purposes only. Additional distribution system layouts are contemplated.

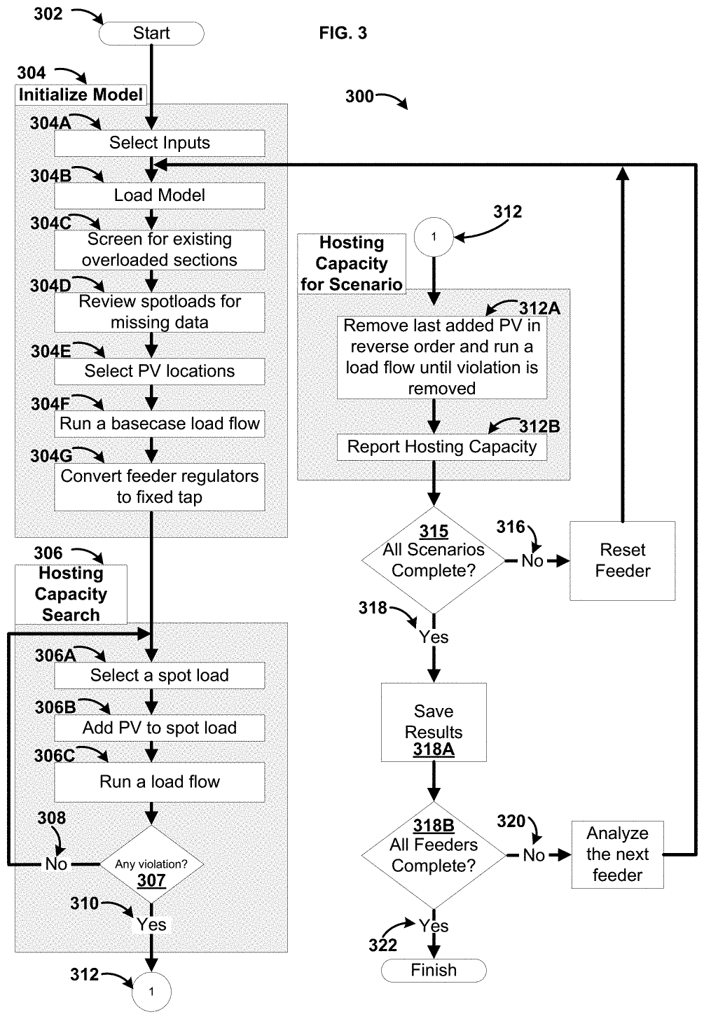

Turning now to FIG. 3, a flowchart is depicted of an exemplary method 300 that a computer 101 may implement in order to assess hosting capacity of a distribution system feeder (e.g., feeder 203). The process may begin at step 302, where a hosting capacity model is initialized 304. The initialization process 304 may include first selecting inputs 304A, such as a type of analysis method to be used, violation limits for feeder performance parameters, distribution system performance criteria, and the like. At step 304B a model is loaded (e.g., a CYME-compatible data file representing a topology of a distribution system under a certain operating condition), and the model is then screened at 304C to determine whether any points in the distribution system being analyzed are overloaded (e.g., an amount of load that violates one or more performance parameters).

Next, spot load points from the model are reviewed to determine whether any corresponding spot load data is missing. The spot load data, as discussed above, may include a customer type (e.g., residential, commercial, industrial, etc.) and a number of kilowatt hours (e.g., representing an amount of kilowatts of power the particular spot load point is demanding). At step 304E a number of spot load points are selected as potential distributed power generation points (e.g., points where PV or DG sources could be installed). After selecting the candidate spot load points, a base case load flow 304F for the feeder is generated and regulators associated with the feeder being analyzed are converted to fixed tap 304G.

The method 300 then moves on to the hosting capacity search 306, which may include several sub-steps. At step 306A, a spot load point (e.g., spot load point 210) that was previously selected as a candidate for potential distributed power generation is randomly selected, and an amount of distributed power generation (e.g., a number of kilowatts) is added to the associated kilowatt value in the spot load data for the randomly selected spot load point. Subsequently, a second load flow for the feeder may be generated, and it can then be determined at 307 whether any of the performance parameters or other criteria selected at 304A are violated (e.g., overload, reverse power flow, etc.). If none of the performance parameters or other criteria are violated, then the hosting capacity search 306 is repeated for a different randomly selected spot load point. The hosting capacity search 306 can continue to iterate until all candidate spot load points are considered and then moves to step 312B. If during the hosting capacity search 306 any randomly selected spot load point that causes any of the performance parameters or other criteria to be violated 310, then the process moves to 312.

At 312, in response to a load flow for a given candidate spot load point violating any of the performance parameters or other criteria, the method 300 undergoes a remediation process whereby the violation is removed. At step 312A the amount of distributed power generation that was added to the associated kilowatt for the last randomly selected spot load point is removed and a load flow for the feeder is then generated (e.g., the amount of distributed power generation added to the last randomly selected spot load point is subtracted from the original kilowatt value associated thereto). Step 312A repeats until the violation is removed (e.g., an amount of distributed power generation may be removed for as few as one spot load point if the most recently considered spot load point is the only one creating a violation). At step 312B a hosting capacity for the feeder for a first scenario is determined (e.g., for the operating conditions associated with the selected inputs and the loaded model). The first scenario may include operating conditions of the distribution system associated with a peak (e.g., maximum load) condition.

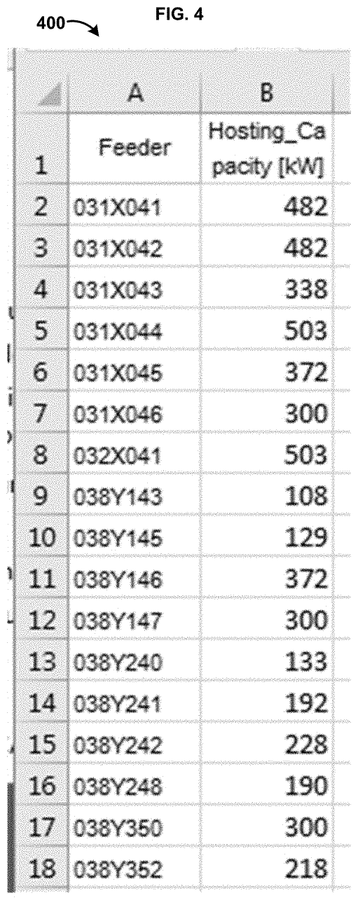

At step 315 it is determined whether all scenarios have been considered. This may include determining whether the hosting capacity has been assessed for all possible operating conditions of the distribution system (e.g., a minimum load condition, an optimal condition, an average condition, etc.). If all of the possible scenarios have not been considered 316, then the feeder is reset and the process begins again at step 304B with a different scenario being considered (e.g., the first scenario included conditions where loads are at their peak, and a second scenario may include conditions where loads are at their average lowest). On the other hand, if all of the possible scenarios have been considered 318, then the results (e.g., the hosting capacity for each scenario) are saved (e.g., in the memory of computer 101). FIG. 4 shows an example set of results 400 from a hosting capacity assessment of a distribution system using method 300. Column A of 400 lists each feeder in the distribution system with specific identifiers for each. Column B of 400 lists the associated hosting capacity that was determined for each feeder (e.g., a number of kilowatts of distributed power generation a given feeder could host/support). Turning back to FIG. 3, at step 318B it is determined whether hosting capacity has been assessed for all feeders in the distribution system. If not all feeders have been assessed 320, then the process repeats again for each remaining feeder. Once all feeders have been assessed 322, the method 300 completes.

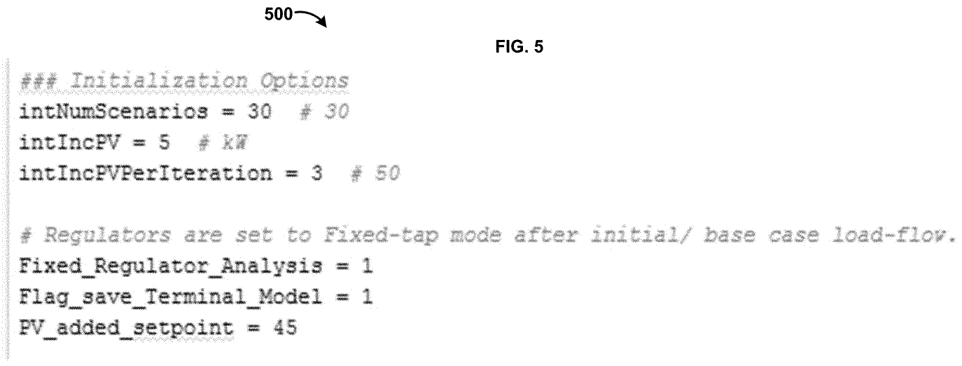

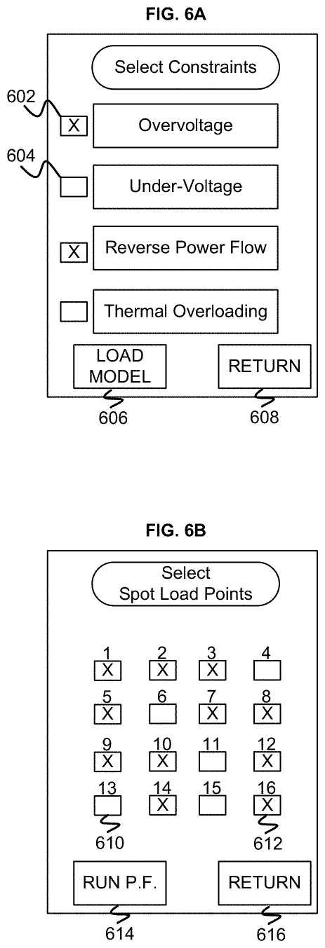

As discussed above, at step 304A a number of selections can be made when the method 300 initializes a model 304, such as a type of analysis method to be used, violation limits for feeder performance parameters, distribution system performance criteria, and the like. FIG. 5 shows a text-based way that a user of the computer 101 can select various values 500 for the model being considered. These selections may include a number of scenarios to consider (e.g., minimum load conditions, maximum load conditions, average load conditions, etc.). The selections may also include a number of kilowatts of distributed power generation (e.g., a number of kilowatts) that is added to an associated kilowatt value in the spot load data for a randomly selected spot load (e.g., every candidate spot load is created by 5 kilowatts). The amount of kilowatts added can also be selected such that it incrementally increases with each iteration of 306. FIG. 6A shows different views of a user interface that may be generated by the computer 101 (e.g., using human machine interface 102) when assessing hosting capacity of a distribution system using method 300.

Similar to the text-based way a user may select options as shown in FIG. 5, the interface in FIG. 6A may allow a user to select one or more constraints, such as overvoltage, to be selected 602 while other constraints, such as under-voltage, may not be selected 604. Once the desired constraints are selected, the user can then select to load a model 606 or return 608 to a previous screen. FIG. 6B shows a view of the interface that allows a user to select one or more spot load points as candidates for distributed power generation. Certain spot load points may be selected 612 while others are not 610. After the candidate spot load points have been chosen, the user generate a power flow 614 for the feeder. The user is also able to select return 616 to go back to a previous screen/view of the interface.

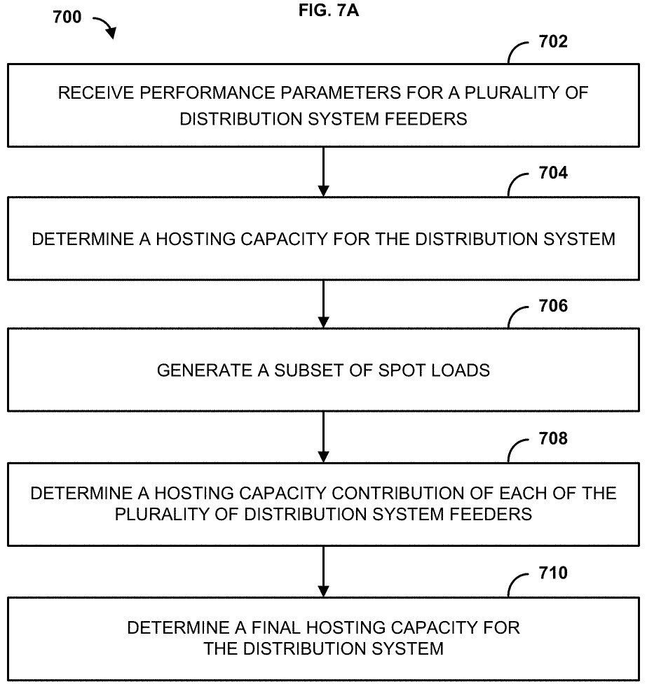

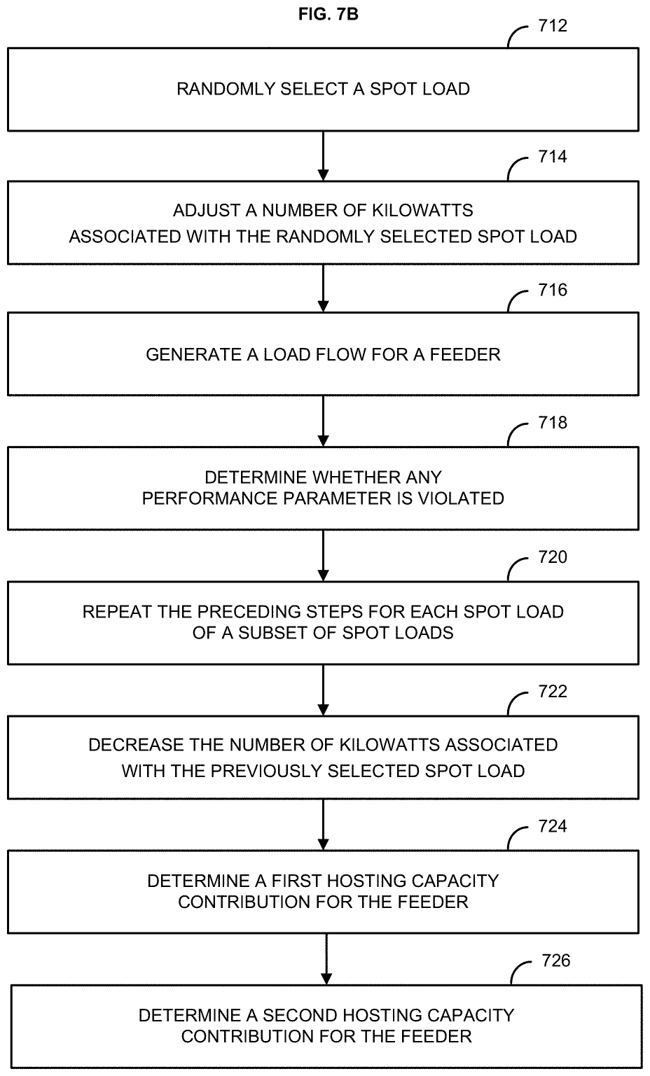

Turning now to FIG. 7, an exemplary method 700 is shown. Method 700 may incorporate some, or even all, steps of method 300. Further, method 700 may be implemented using computer 101. At step 702, a plurality of performance parameters corresponding to each of a plurality of distribution system feeders may be received (e.g., directly from an interface between distribution system 200 and the computer 101; retrieved from the system memory 112, mass storage device 104, and/or network 115). At step 704 a hosting capacity for the distribution system may be determined. In order to determine the hosting capacity for the distribution system overall (e.g., considering all feeders that are part of the distribution system), step 704 may include executing steps 706, 708, and 710.

At step 706 a subset of spot loads from among a plurality of spot loads can be generated (e.g., spot loads are selected as candidates for adding distributed power generation). Each spot load in the subset may have one or more associated characteristics, such as a customer type (e.g., residential, commercial, industrial, etc.) and a number of kilowatts (e.g., an amount of electrical power currently demanded at a given spot load point). When generating the subset of spot loads, it may first be determined for each spot load of the plurality of spot loads whether each associated characteristic is anomalous or non-anomalous. An anomalous characteristic may be a customer type indicative of a null value (e.g., blank entry in received spot load data) or a number of kilowatts indicative of zero.

To avoid the hosting capacity assessment from prematurely halting (e.g., crashing, terminating, etc.) a state of at least one anomalous characteristic (e.g., a blank entry in a customer data field) may be modified (e.g., by the computer 101) such that the modified state is indicative of the characteristic being non-anomalous (e.g., a blank data field is replaced with “commercial” or “residential”). For an anomalous customer type data field, the modified state of the field may be based upon an associated amount of kilowatts (e.g., residential customers may be associated with a range of kilowatts that is less than a range associated with commercial customers). Additionally, for anomalous kilowatt values, the modified state of may be based upon an associated customer type (e.g., a number of kilowatts for a spot load point corresponding to a residential customer may be modified such that it falls within a range associated residential customers). Thus, the subset of spot loads that is generated may only include spot loads of the plurality that are associated with only non-anomalous characteristics (e.g., customer data field is not null/blank; an associated kilowatt amount is not zero). At step 708, based on the generated subset of spot loads and the plurality of performance parameters, a hosting capacity contribution of each feeder in the distribution system may be determined. At step 710, based on the determined hosting capacity contribution of each of feeder, a final hosting capacity for the distribution system can be determined (e.g., an aggregate value of each hosting capacity contribution for each feeder).

FIG. 7B shows a series of sub-steps that may be implemented when determining a hosting capacity contribution of each feeder in the distribution system at step 708. At step 712 a spot load from among the subset of spot loads may be randomly selected for adding an amount of distributed power generation. At step 714 a number of kilowatts associated with a characteristic of the randomly selected spot load may be adjusted by a specified amount (e.g., an amount of distributed power generation), which may be defined by the user when the model. At step 716 a load flow for the feeder may be generated. This load flow may be based on the adjusted number of kilowatts (e.g., thereby accounting for the added distributed power generation). At step 718 it may be determined whether any of the plurality of performance parameters is violated based on based on the load flow for the feeder (e.g., determine whether adding the distributed power generation causes one or more of the performance parameters to be violated).

In response to determining that no performance parameter of the plurality is violated, at step 720 the preceding steps may be repeated for each spot load of the subset of spot loads. This may include randomly selecting a different spot load from the plurality, adjusting the associated kilowatts, generating a load flow for the feeder (e.g., considering the first randomly selected spot load as well as the current one), and also determining whether any performance parameter is violated. On the other hand, in response to determining that at least one of the plurality of performance parameters is violated, the number of kilowatts associated with the kilowatt characteristic of the previously selected spot load may be decreased by the same amount by which it was previously increased.

Next, at step 724, based on the generated load flows for the feeder (e.g., each load flow generated as each spot load is randomly selected), a first hosting capacity contribution for the feeder may be determined. A second hosting capacity contribution for the feeder can similarly be determined for the feeder. When the first hosting capacity contribution is determined, the amount by which the kilowatt values are adjusted may be indicative of a peak load for the feeder. Likewise, the amount by which the kilowatt values are adjusted when determining the second hosting capacity contribution may be indicative of a minimum load for the feeder. The final hosting capacity for a given feeder determined at 710 may therefore be based on the first hosting capacity contribution of the given feeder when the second hosting capacity contribution of the given feeder is greater than the first hosting capacity contribution (e.g., a greater value of kilowatt hours). Alternatively, the final hosting capacity for a given feeder may be based on the first hosting capacity contribution of the given feeder when the second hosting capacity contribution of the given feeder when the first hosting capacity contribution of the given feeder is greater than the second hosting capacity contribution.

As one skilled in the art can appreciate, the present methods and systems offer an array of advantages over existing methodologies that assess hosting capacity of a distribution system. By randomly selecting spot load points as candidate locations at which to install a distributed power generation source, the present methods and systems—unlike existing methodologies—emulate a natural pattern of adoption of distributed power generation (e.g., adoption may not follow any predictable pattern). The present methods and systems are also highly customizable as compared to predecessors. As discussed above with respect to the constraint options shown in FIG. 5 and the interfaces shown in FIG. 6, the present methods and systems may consider multiple constraints in a single analysis (e.g., multiple constraints such as feeder overvoltage, feeder under-voltage, reverse power flow, thermal overloading, etc., can be simultaneously considered).

Further, the present methods and systems analyze a feeder not only at an operational level that may be considered to be a ‘peak load’ but also at a proportionately reduced load (e.g., ‘minimum load’). This is accomplished by selecting inputs at step 304A and a model at step 304B that are representative of the distribution system at varying levels of operational intensity. A high level of operational intensity—a peak load—may be represented by inputs and aspects of a given model that assign a higher level of demand to the feeder being analyzed (e.g., a high/peak load would have a higher value of kilowatts as compared with a reduced/minimum load). In some cases the outcome of the hosting capacity analysis under both peak and minimum conditions are used as a basis by which a final hosting capacity can be determined. This means the higher value of hosting capacity may be selected as the final hosting capacity. In some cases, however, the final hosting capacity may be a minimum of the two. This approach takes into account the special cases that can occur at specific loading levels (e.g., providing a buffer of excess hosting capacity to account for sudden surges in demand for power at specific nodes in a feeder).

The present methods and systems also improve upon existing methodologies by remediating imperfect input data, such as missing customer information or kilowatt values for a given spot load point. As discussed above, the present methods and systems can nevertheless carry out a hosting capacity analysis in the absence of certain spot load data. In a case where customer information is missing for a given spot load (e.g., a null value in a data field that indicates a customer type), the corresponding kilowatt value can be used to determine the customer type. A residential customer may, on average, have a kilowatt value that is much less than a kilowatt value for a commercial customer. By assessing the value of kilowatts for the given spot load against pre-existing known ranges (e.g., stored in the system memory 112, mass storage device 104, or network 115), the present methods and systems can accommodate the missing customer information and derive a likely value for the field (e.g., residential, commercial, or industrial).

In cases where the customer information is known for a given spot load, but the corresponding kilowatt value is zero or null, the same pre-existing known ranges can be used to determine an appropriate amount for the kilowatt value. When the hosting capacity model or selected inputs are indicative of a peak load, the determined kilowatt value for the given spot load may be closer to a highest value within the pre-existing range for that type of customer. Conversely, when the hosting capacity model or selected inputs are indicative of a minimum load, the determined kilowatt value for the given spot load may be closer to a lowest value within the pre-existing range for that type of customer. By being capable of remediating imperfect input data, the present methods and systems have higher levels of robustness and stability as compared with existing methodologies to assess hosting capacity.

The array of advantages the present methods and systems offer over existing methodologies makes the results especially useful for infrastructure planners and engineers. Knowing a distribution system's hosting capacity on a feeder-by-feeder level allows planners and engineers to design new infrastructure and upgrade existing infrastructure in such a way as to ensure optimal system performance. While the disclosed methods and systems have been described in connection with preferred configurations and specific examples, it is not intended that the scope be limited to the particular embodiments set forth, as the embodiments herein are intended in all respects to be illustrative rather than restrictive. Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

It will be apparent to those skilled in the art that various modifications and variations can be made without departing from the scope or spirit. Other embodiments will be apparent to those skilled in the art from consideration of the specification and practice disclosed herein. It is intended that the specification and examples be considered as exemplary only, with a true scope and spirit being indicated by the following claims.

What is claimed is:

1. A method comprising:
receiving a plurality of performance parameters for a plurality of distribution system feeders; and
determining, based on at least the plurality of performance parameters, a hosting capacity for the distribution system by:
generating a subset of spot loads from among a plurality of spot loads, wherein each spot load comprises one or more characteristics;
determining, based on the subset of spot loads and the plurality of performance parameters, a hosting capacity contribution of each of the plurality of distribution system feeders; and
determining, based on the hosting capacity contribution of each of the plurality of distribution system feeders, a final hosting capacity for the distribution system.

2. The method of claim 1, wherein generating the subset of spot loads from among the plurality of spot loads comprises:
determining whether each characteristic associated with each of the plurality of spot loads is anomalous or non-anomalous;
modifying a state of at least one anomalous characteristic such that the modified state is indicative of the characteristic being non-anomalous; and
generating a subset of spot loads comprising one or more of the plurality of spot loads, wherein all characteristics associated with spot loads of the subset are non-anomalous.

3. The method of claim 2, wherein the characteristics comprise a customer type and a number of kilowatts.

4. The method of claim 3, wherein an anomalous characteristic comprises one or more of a customer type indicative of a null value or a number of kilowatts indicative of zero.

5. The method of claim 4, wherein determining a hosting capacity contribution of each of the plurality of distribution system feeders comprises:
(a) selecting, at random, a spot load from among the subset of spot loads;
(b) adjusting, by a specified amount, a number of kilowatts associated with a characteristic of the randomly selected spot load,
(c) generating, based on the adjusted number of kilowatts, a load flow for the feeder,
(d) determining, based on the load flow for the feeder, whether any of the plurality of performance parameters is violated,
(e) responsive to determining that the plurality of performance parameters are not violated, repeating steps (a)-(d) for each spot load of the subset of spot loads,
(f) responsive to determining that at least one of the plurality of performance parameters is violated, decreasing, by the adjusted amount, the number of kilowatts associated with the characteristic of the previously selected spot load, and
(g) determining, based on the generated load flows for the feeder, a first hosting capacity contribution for the feeder.

6. The method of claim 5, wherein the adjusted number of kilowatts is indicative of a peak load.

7. The method of claim 5, further comprising:
(f) determining a second hosting capacity contribution for the feeder by repeating steps (a)-(f), wherein the adjusted number of kilowatts is indicative of a minimum load.

8. The method of claim 7, wherein the hosting capacity contribution for a given feeder of the plurality of distribution system feeders comprises the first hosting capacity contribution of the given feeder when the second hosting capacity contribution of the given feeder is greater than the first hosting capacity contribution.

9. The method of claim 8, wherein the hosting capacity contribution for a given feeder of the plurality of distribution system feeders comprises the second hosting capacity contribution of the given feeder when the first hosting capacity contribution of the given feeder is greater than the second hosting capacity contribution.

10. The method of claim 1, wherein the plurality of performance parameters comprises one or more of overvoltage, under-voltage, reverse power flow, or thermal overloading.

11. The method of claim 4, wherein modifying a state of at least one anomalous characteristic such that the modified state is indicative of the characteristic being non-anomalous comprises:
determining a customer type associated with a value of a first characteristic of a given spot load; and
modifying, based on the customer type, a state of a second characteristic of the given spot load determined to be anomalous and comprising a number of kilowatts indicative of zero.

12. A system comprising:
a memory having computer-executable instructions encoded thereon; and
a processor functionally coupled to the memory and configured, by the computer-executable instructions, to cause the system to perform the following steps:
receive, with a network interface, a plurality of performance parameters for a plurality of distribution system feeders; and
determine, based on at least the plurality of performance parameters, a hosting capacity for the distribution system feeders by:
generating a subset of spot loads from among a plurality of spot loads, wherein each spot load comprises one or more characteristics;
determining, based on the subset of spot loads and the plurality of performance parameters, a hosting capacity contribution of each of the plurality of distribution system feeders; and
determining, based on the hosting capacity contribution of each of the plurality of distribution system feeders, a final hosting capacity for the distribution system.

13. The system of claim 12, wherein generating the subset of spot loads from among the plurality of spot loads comprises:
determining whether each characteristic associated with each of the plurality of spot loads is anomalous or non-anomalous;
modifying a state of at least one anomalous characteristic such that the modified state is indicative of the characteristic being non-anomalous; and
generating a subset of spot loads comprising one or more of the plurality of spot loads, wherein all characteristics associated with spot loads of the subset are non-anomalous.

14. The system of claim 13, wherein the characteristics comprise a customer type and a number of kilowatts.

15. The system of claim 14, wherein an anomalous characteristic comprises one or more of a customer type indicative of a null value or a number of kilowatts indicative of zero

16. The system of claim 15, wherein determining a hosting capacity contribution of each of the plurality of distribution system feeders comprises:
(a) selecting, at random, a spot load from among the subset of spot loads;
(b) adjusting, by a specified amount, a number of kilowatts associated with a characteristic of the randomly selected spot load,
(c) generating, based on the adjusted number of kilowatts, a load flow for the feeder,
(d) determining, based on the load flow for the feeder, whether any of the plurality of performance parameters is violated,
(e) responsive to determining that the plurality of performance parameters are not violated, repeating steps (a)-(d) for each spot load of the subset of spot loads,
(f) responsive to determining that at least one of the plurality of performance parameters is violated, decreasing, by the adjusted amount, the number of kilowatts associated with the characteristic of the previously selected spot load, and
(g) determining, based on the generated load flows for the feeder, a first hosting capacity contribution for the feeder.

17. The system of claim 16, wherein the adjusted number of kilowatts is indicative of a peak load.

18. The system of claim 17, further comprising:
(f) determining a second hosting capacity contribution for the feeder by repeating steps (a)-(f), wherein the adjusted number of kilowatts is indicative of a minimum load.

19. The system of claim 18, wherein the hosting capacity contribution for a given feeder of the plurality of distribution system feeders comprises the first hosting capacity contribution of the given feeder when the second hosting capacity contribution of the given feeder is greater than the first hosting capacity contribution.

20. A method comprising:
(a) selecting, by a computing device at random, a spot load from among the subset of spot loads for a feeder;
(b) adjusting, by a specified amount, a number of kilowatts associated with a characteristic of the randomly selected spot load,
(c) generating, based on the adjusted number of kilowatts, a load flow for the feeder,
(d) determining, based on a load flow for the feeder, whether any of a plurality of performance parameters is violated,
(e) responsive to determining that the plurality of performance parameters are not violated, repeating steps (a)-(d) for each spot load of the subset of spot loads,
(f) responsive to determining that at least one of the plurality of performance parameters is violated, decreasing, by the adjusted amount, a number of kilowatts associated with the characteristic of the previously selected spot load, and
(g) determining, based on the generated load flows for the feeder, a first hosting capacity contribution for the feeder.
